(19) United States
(12) Patent Application Publication
(10) Pub. No.: US 2026/0147064 A1
(43) Pub. Date: May 28, 2026

(54) INSPECTION DEVICE AND INSPECTION METHOD

(71) Applicant: TOKYO WELD CO., LTD., Tokyo-to (JP)

(72) Inventors: Taiyo KOMORI, Tokyo-to (JP); Shunsuke SASAKI, Tokyo-to (JP); Yoshikazu SASAOKA, Tokyo-to (JP)

(73) Assignee: TOKYO WELD CO., LTD., Tokyo-to (JP)

(21) Appl. No.: 19/392,727

(22) Filed: Nov. 18, 2025

(30) Foreign Application Priority Data
Nov. 22, 2024 (JP) 2024-203907

(51) Int. Cl. G01R 31/64

(52) U.S. Cl. CPC G01R 31/64

(57) ABSTRACT

An inspection device includes: a charging unit that performs charging of a capacitor; a discharging unit that performs discharging the capacitor; a current measurement unit that continuously measures current of the capacitor during the discharging; and an abnormality detection unit that detects an abnormality of the capacitor based on a regression line relating to a discharge characteristic, the regression line being derived from a logarithm of measured values of the current in a determination time range during the discharging and a logarithm of measurement timings of the current.

### CROSS-REFERENCE TO RELATED APPLICATIONS

This application is based upon and claims the benefit of priority from Japanese Patent Application No. 2024-203907, filed on November 22, 2024; the entire contents of which are incorporated herein by reference.

### TECHNICAL FIELD

The present disclosure relates to an inspection device and an inspection method for detecting an abnormality of a capacitor.

### BACKGROUND ART

Capacitors such as MLCCs (Multi-Layer Ceramic Capacitors) and electronic components including capacitors are generally subjected to inspection for detecting defective products and are then shipped. In recent years in particular, a large number of MLCCs have come to be used in devices such as automobiles and communication equipment that require a high level of performance and safety, and it is desired to perform inspection that guarantees the reliability of a large quantity of MLCCs at a higher level.

Regarding such inspection, for example, Japanese patent application publication No. 09-152455 discloses a defect detection device intended to detect and screen internal defects such as foreign matter contamination or pinholes in a multilayer ceramic capacitor in a short period of time. Further, Japanese patent application publication No. 2000-228337 discloses a method for determining acceptability intended to determine whether a capacitor is acceptable or not in a short period of time.

### SUMMARY OF THE INVENTION

The present disclosure has been made in view of the above circumstances, and an object thereof is to provide a technique that is advantageous for accurately detecting an abnormality of a capacitor.

An aspect of the presenter disclosure is directed to an inspection device comprising: a charging unit that performs charging of a capacitor; a discharging unit that performs discharging the capacitor; a current measurement unit that continuously measures current of the capacitor during the discharging; and an abnormality detection unit that detects an abnormality of the capacitor based on a regression line relating to a discharge characteristic, the regression line being derived from a logarithm of measured values of the current in a determination time range during the discharging and a logarithm of measurement timings of the current.

The current measurement unit may continuously measure the current of the capacitor during the charging, and the abnormality detection unit may detect an abnormality of the capacitor based on a regression line relating to a charging characteristic, the regression line being derived from a logarithm of measured values of the current in a determination time range during the charging and a logarithm of measurement timings of the current.

The abnormality detection unit may detect an abnormality of the capacitor based on a degree of coincidence between the logarithm of the measured values of the current and the logarithm of the measurement timings of the current with respect to the regression line.

The abnormality detection unit may detect an abnormality of the capacitor based on a relationship of the logarithm of the measured values of the current with respect to at least one of an upper limit and a lower limit of a current allowable range determined with reference to the regression line over the determination time range.

The abnormality detection unit may detect an abnormality of the capacitor based on a first regression line derived from a logarithm of measured values of the current in a first determination time range during the discharging and a logarithm of measurement timings of the current, and the abnormality detection unit may detect an abnormality of the capacitor based on a second regression line derived from a logarithm of measured values of the current in a second determination time range during the discharging and a logarithm of measurement timings of the current.

After the charging unit applies a voltage to the capacitor with a first polarity to perform first polarity charging, the discharging unit may perform first polarity discharging of the capacitor; after the charging unit applies a voltage to the capacitor with a second polarity to perform second polarity charging, the discharging unit may perform second polarity discharging of the capacitor; the current measurement unit may measure a first polarity discharging current which is a current of the capacitor during the first polarity discharging; the current measurement unit may measure a second polarity discharging current which is a current of the capacitor during the second polarity discharging; the abnormality detection unit may detect an abnormality of the capacitor based on a first polarity regression line derived from a logarithm of measured values of the first polarity discharging current in a first determination time range during the first polarity discharging and a logarithm of measurement timings of the first polarity discharging current; and the abnormality detection unit may detect an abnormality of the capacitor based on a second polarity regression line derived from a logarithm of measured values of the second polarity discharging current in a second determination time range during the second polarity discharging and a logarithm of measurement timings of the second polarity discharging current.

Another aspect of the present disclosure is directed to an inspection method comprising the steps of: performing charging of a capacitor; performing discharging the capacitor; measuring current of the capacitor during the discharging in a continuous manner; and detecting an abnormality of the capacitor based on a regression line relating to a discharge characteristic, the regression line being derived from a logarithm of measured values of the current in a determination time range during the discharging and a logarithm of measurement timings of the current.

According to the present disclosure, it is advantageous for accurately detecting an abnormality of a capacitor.

### BRIEF DESCRIPTION OF DRAWINGS

FIG. 1 is a perspective view schematically illustrating an example of an inspection system for electronic components;

FIG. 2 is a front view of the inspection system shown in FIG. 1;

FIG. 3 is a diagram illustrating an example of a configuration of an inspection device;

FIG. 4 is a circuit diagram illustrating an example of a charging unit and a discharging unit (electrical circuit);

FIG. 5 is a graph (linear-scale graph) illustrating an example of a measurement result of leakage current of an electronic component (capacitor) during charging;

FIG. 6 is a graph (log-log graph) illustrating an example of a measurement result of leakage current of an electronic component during charging, which is a graph for explaining a first charging abnormality detection method;

FIG. 7 is a graph (log-log graph) illustrating an example of a measurement result of leakage current of an electronic component during charging, which is a graph for explaining a second charging abnormality detection method;

FIG. 8 is a graph (log-log graph) illustrating an example of a measurement result of leakage current of an electronic component during discharging, which is a graph for explaining a first discharging abnormality detection method;

FIG. 9 is a graph (log-log graph) illustrating an example of a measurement result of leakage current of an electronic component during discharging, which is a graph for explaining a second discharging abnormality detection method;

FIG. 10 is a log-log graph of "charging time versus measured current" illustrating an example of general electrical characteristics of a capacitor;

FIG. 11 is a log-log graph of "discharging time versus measured current" illustrating an example of general electrical characteristics of a capacitor; and

FIG. 12 is a flowchart illustrating an example of an inspection method for detecting an abnormality of an electronic component (capacitor).

### DETAILED DESCRIPTION

Hereinafter, exemplary embodiments of the present disclosure will be described with reference to the drawings.

An electronic component W to be inspected in the following description may be a capacitor itself, or an electronic component including a capacitor as a constituent component. The specific type of a capacitor to be inspected is not limited, and the following techniques can be applied to an MLCC, a tantalum capacitor and other general capacitors.

### Inspection System

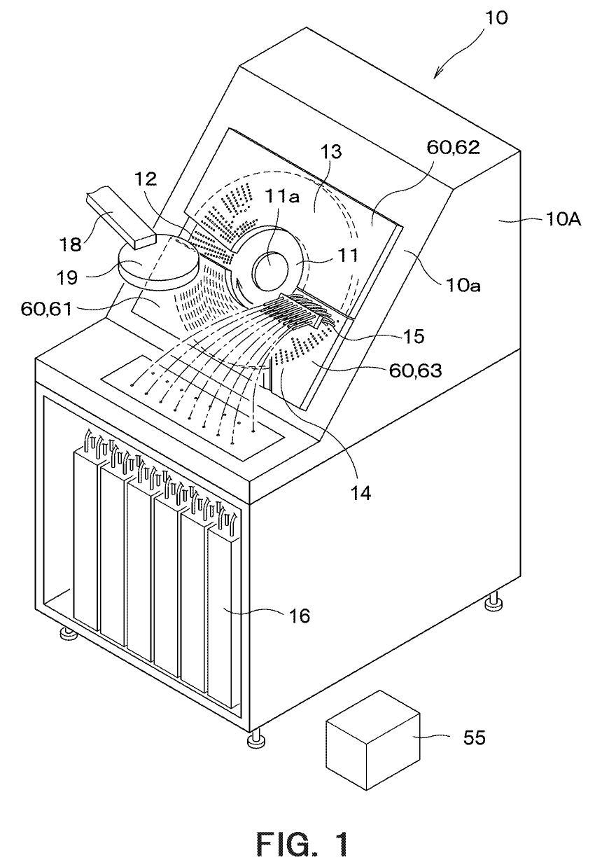

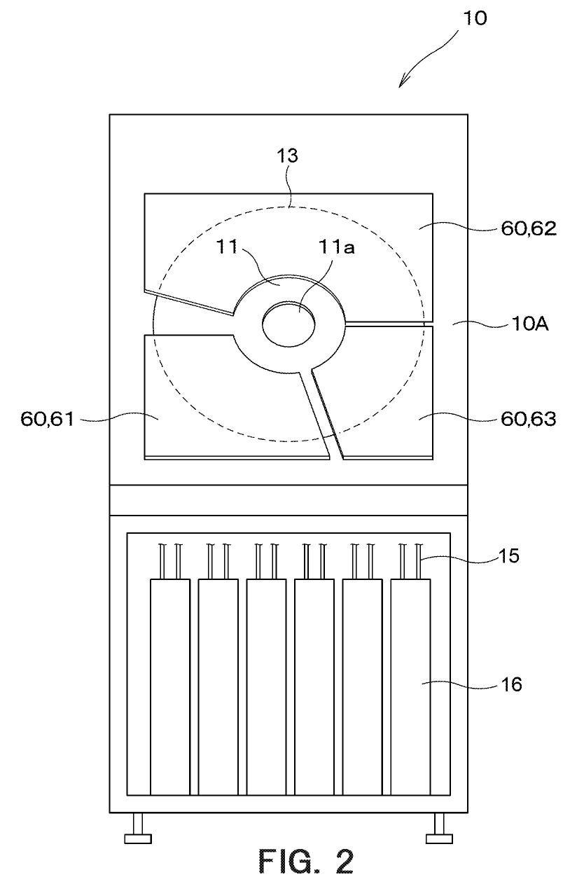

FIG. 1 is a perspective view schematically illustrating an example of an inspection system 10 for electronic components. FIG. 2 is a front view of the inspection system 10 shown in FIG. 1. In FIG. 2, for ease of understanding, illustration of some components shown in FIG. 1 (for example, a supply feeder 18, an electronic component supply unit 19, and a control unit 55) is omitted.

The inspection system 10 shown in FIGS. 1 and 2 includes a structural member 10A, an index table 11 provided on an inclined surface 10a of the structural member 10A, an inspection device 13, an electronic component discharging unit 14, discharge paths 15, and a collection device 16.

The index table 11 has a disk shape, is provided so as to be intermittently rotatable about a rotational shaft 11a, and has a large number of pockets 12 for accommodating electronic components to be inspected. The large number of pockets 12 form a plurality of rows (for example, sixteen rows) in a radial direction of the index table 11, and in each row, a plurality of the pockets 12 are arranged at equal angular intervals in a circumferential direction of the index table 11.

The index table 11 is covered by an index table cover 60 from both a front surface side and a rear surface side. The index table cover 60 on the front surface side includes a first front cover 61, a second front cover 62, and a third front cover 63, which are arranged adjacent to one another with gaps therebetween. A large number of electronic components to be inspected are supplied from the supply feeder 18 to the electronic component supply unit 19, and are supplied from the electronic component supply unit 19 to the pockets 12 via the index table cover 60 (in the example shown in FIGS. 1 and 2, via the first front cover 61).

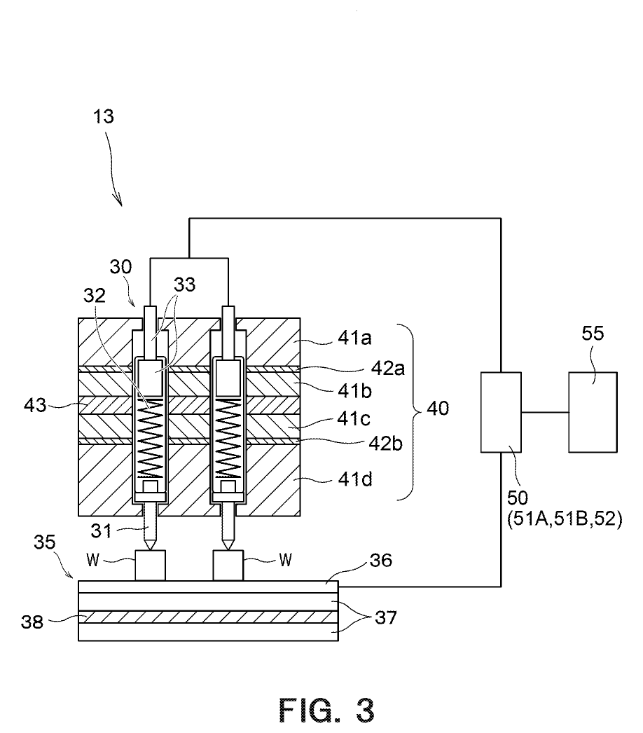

The inspection device 13 performs electrical inspection of electronic components accommodated in the respective pockets 12. The inspection device 13 of the present example can perform inspection of electronic components in an environment at normal temperature (for example, 5°C to 35°C), but as will be described later, can also perform electrical inspection while actively applying a thermal load (for example, a thermal load of approximately 100°C to 170°C) to each electronic component. A specific configuration example of the inspection device 13 will be described later (see FIG. 3).

The electronic component discharging unit 14 discharges electronic components that have undergone electrical inspection by the inspection device 13, to the collection device 16 via the discharge paths 15, for example, using compressed air. The collection device 16 has a plurality of collection boxes (in the example shown in FIGS. 1 and 2, six collection boxes). The electronic component discharging unit 14 sends each electronic component from a pocket 12 (the index table 11) toward a corresponding collection box in accordance with the result of the electrical inspection. The electronic component discharging unit 14 operates under the control of the control unit 55 in such a manner that electronic components determined to be normal and electronic components determined to have an abnormality as a result of the electrical inspection are discharged into different collection boxes. The electronic component discharging unit 14 may discharge electronic components into different collection boxes according to the type or degree of the abnormality based on the result of the electrical inspection, or may discharge electronic components into different collection boxes according to conditions other than the result of the electrical inspection.

According to the inspection system 10 described above, when the index table 11 is intermittently rotated in the clockwise direction in FIGS. 1 and 2 with electronic components to be inspected accommodated in respective pockets 12, the electronic components W in the respective pockets 12 are gradually conveyed downstream. The electronic components W in the respective pockets 12 undergo electrical inspection by the inspection device 13 at an inspection position on the conveyance path, and are sorted and collected by the electronic component discharging unit 14, the discharge paths 15, and the collection device 16 according to the result of the inspection.

The inspection system 10 shown in FIGS. 1 and 2 can be implemented based on known techniques, and a more detailed description of the configuration of the inspection system 10 is omitted. The inspection system 10 of the present embodiment may be configured, for example, in the same manner as the apparatus disclosed in Japanese patent application publication No. 2023-5282.

### Inspection Device

FIG. 3 is a diagram illustrating an example of a configuration of the inspection device 13. In FIG. 3, some elements (for example, a probe holder 40 and an electrode unit 35) are shown in cross section. Further, in FIG. 3, illustration of the index table 11 (including the pockets 12) and the like is omitted; however, each electronic component W shown in FIG. 3 is accommodated in a corresponding pocket 12 and is intermittently stopped at the inspection position located in the middle of the conveyance path by the index table 11.

The inspection device 13 shown in FIG. 3 includes a plurality of probe units 30, a probe holder 40, and an electrode unit 35.

The number of probe units 30 is not limited, but a number of probe units 30 corresponding to the number of electronic components W to be inspected simultaneously (for example, the number of pockets 12 arranged in the radial direction of the index table 11) are provided. Each probe unit 30 includes a probe 31, a compression spring 32, and a probe base 33. The probe 31, the compression spring 32, and the probe base 33 each include an electrical conductor having high electrical conductivity, and preferably have high thermal conductivity. The probe base 33 is electrically connected to an electrical circuit 50. The compression spring 32 is positioned between the probe 31 and the probe base 33 and is electrically connected to each of the probe 31 and the probe base 33. The probe 31 is supported by the probe holder 40 so as to be movable forward and backward while receiving an elastic force from the compression spring 32, in such a manner that the probe 31 partially protrudes from the probe holder 40.

The probe holder 40 that supports each probe unit 30 has a laminated structure including holder bodies 41a, 41b, 41c, 41d, sheet materials 42a, 42b, and a probe heater 43. The sheet material 42a is provided between the holder body 41a and the holder body 41b, the probe heater 43 is provided between the holder body 41b and the holder body 41c, and the sheet material 42b is provided between the holder body 41c and the holder body 41d.

The holder bodies 41a, 41b, 41c, 41d have relatively low thermal conductivity and electrical conductivity, and are made of, for example, Photoveel material (Ferrotec Corporation). On the other hand, the sheet materials 42a, 42b have relatively high thermal conductivity and electrical conductivity, and are made of, for example, a graphite material. The probe heater 43 is capable of generating heat under the control of the control unit 55, and is constituted by, for example, a rubber heater. Heat from the probe heater 43 is efficiently transmitted to each probe unit 30 (in particular, the probe 31) via the sheet materials 42a, 42b.

The electrode unit 35 has a laminated structure including an electrode 36, electrode bases 37, and an electrode heater 38. The electrode 36 is electrically connected to the electrical circuit 50. The electrode bases 37 support the electrode 36. The electrode heater 38 is provided so as to be covered by the electrode bases 37 on both the front surface side and the rear surface side, is capable of generating heat under the control of the control unit 55, and is constituted by, for example, a rubber heater. Heat from the electrode heater 38 is transmitted to the electrode 36 via the electrode bases 37. From the viewpoint of efficiently heating the electrode 36 by the electrode heater 38, it is preferable that the electrode bases 37 (in particular, the electrode base positioned between the electrode heater 38 and the electrode 36) be made of a material having excellent heat transfer properties.

The electrical circuit 50 is connected to each probe unit 30 (in the example shown in FIG. 3, each probe base 33) and the electrode 36. While the probe 31 is away from an electronic component W to be inspected, the probe unit 30, the electronic component W, the electrode unit 35 (in particular, the electrode 36), and the electrical circuit 50 form an open circuit structure as a whole. On the other hand, when an electronic component W to be inspected is sandwiched between the probe 31 and the electrode 36 and the probe 31 and the electrode 36 come into contact with the electronic component W, a closed circuit including the probe unit 30, the electronic component W, the electrode unit 35 (in particular, the electrode 36), and the electrical circuit 50 is formed.

The electrical circuit 50 of the present example functions, under the control of the control unit 55, as a charging unit 51A that applies a voltage to an electronic component W (capacitor) to perform charging and as a discharging unit 51B that performs discharging of an electronic component W (capacitor), and also functions as a current measurement unit 52 capable of continuously measuring the current of the electronic component W (capacitor) during charging and discharging. In particular, the electrical circuit 50 (the charging unit 51A) provided as part of the inspection system 10 is configured to be capable of applying a relatively large electrical load to an electronic component W to be inspected. The magnitude of such an electrical load can be changed by the control unit 55 controlling the electrical circuit 50 (the charging unit 51A), and a direct current voltage of, for example, several times (for example, 2.5 times) the rated voltage of the electronic component W may be applied to the electronic component W.

The control unit 55 functions as an abnormality detection unit that detects an abnormality of each electronic component W (in particular, a capacitor) based on the measurement result of the electrical circuit 50 (the current measurement unit 52). A specific example of a method for detecting an abnormality of each electronic component W by the control unit 55 will be described later.

According to the inspection device 13 described above, while the index table 11 is intermittently stopped, an electronic component W in each pocket 12 (see FIG. 1) located at the inspection position is sandwiched between the electrode 36 and a corresponding probe 31. When sandwiching an electronic component W between the electrode 36 and a probe 31, the electrode unit 35 and/or each probe unit 30 (and hence the probe holder 40) may be moved by a device (not shown in the drawings) in such a manner that the electrode 36 and the probe 31 are brought closer to each other from a state in which the electrode 36 and the probe 31 are relatively spaced apart from each other.

A test voltage is applied by the electrical circuit 50 functioning as the charging unit 51A to an electronic component W clamped between the electrode 36 and the probe 31, and a minute current (leakage current: charging current) flowing through the electronic component W is measured by the electrical circuit 50 functioning as the current measurement unit 52. In this manner, the leakage current of the electronic component W during charging is continuously measured, and the result of the measurement is sent from the electrical circuit 50 to the control unit 55.

After charging, the electronic component W clamped between the electrode 36 and the probe 31 is connected to a resistor by the electrical circuit 50 functioning as the discharging unit 51B and is discharged, and a minute current (leakage current: discharging current) flowing through the electronic component W is measured by the electrical circuit 50 functioning as the current measurement unit 52. In this manner, the leakage current of the electronic component W during discharging is continuously measured, and the result of the measurement is sent from the electrical circuit 50 to the control unit 55.

The continuous measurement of the leakage current of an electronic component W can be performed at arbitrary time intervals; however, from the viewpoint of improving the accuracy of determination of the presence or absence of an abnormality of an electronic component W, it is preferable that the leakage current of an electronic component W be continuously measured at as short a time interval as possible. In a general measuring device, measurement of the leakage current of an electronic component W is usually performed at a time interval of about 10 ms (milliseconds) to 100 ms. On the other hand, the inspection system 10 of the present embodiment can also perform continuous measurement of the leakage current of an electronic component W at a time interval shorter than 10 ms, and by continuously measuring the leakage current of an electronic component W at a time interval of, for example, 5 ms or less (more preferably, 1 ms or less), it is possible to accurately detect an abnormality of the electronic component W that is difficult to detect in a normal measurement by a general measuring device.

When measuring the electrical characteristics (leakage current characteristics) of an electronic component W in a state where a thermal load is applied, the electrode heater 38 and/or the probe heater 43 is heated to a desired temperature under the control of the control unit 55. As a result, the electrode 36 and/or the probes 31 is heated, and while the electrode 36 and the probes 31 are in contact with an electronic component W, heating of the electronic component W (application of thermal load) can be performed along with charging, discharging, and leakage current measurement of the electronic component W.

The control unit 55 determines the presence or absence of an abnormality of each electronic component W based on the measurement result of the leakage current of each electronic component W provided from the electrical circuit 50.

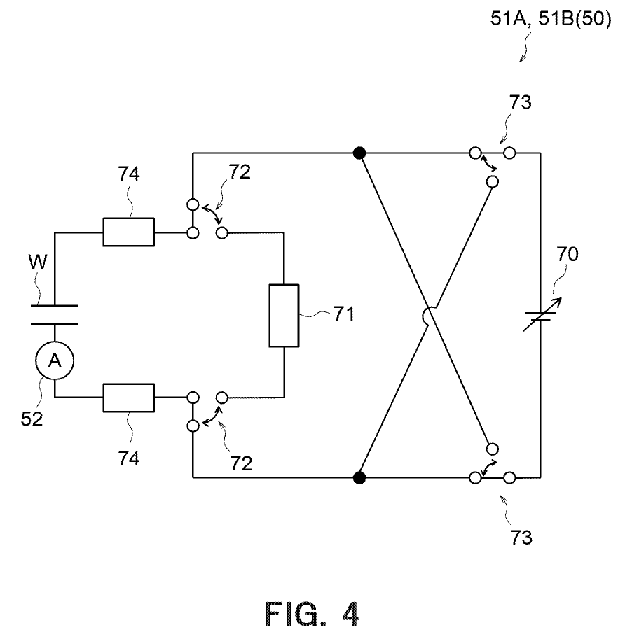

FIG. 4 is a circuit diagram illustrating an example of the charging unit 51A and the discharging unit 51B (the electrical circuit 50).

In the electrical circuit 50 shown in FIG. 4, a power supply 70 is connected to an electronic component (capacitor) W and a resistor 71 via a charge/discharge changeover switch 72.

The power supply 70 is a variable power supply whose output (for example, output voltage) is adjustable. Polarity changeover switches 73 are provided respectively on the positive side and the negative side of the power supply 70. These two polarity changeover switches 73 perform wiring switching in conjunction with each other in such a manner that when one of the charge/discharge changeover switches 72 is connected to the positive side of the power supply 70, the other charge/discharge changeover switch 72 is connected to the negative side of the power supply 70.

Each charge/discharge changeover switch 72 is provided between an electronic component W and the resistor 71, and is switched so as to connect the electronic component W selectively either to one of the resistor 71 or to the polarity changeover switch 73 (and hence the power supply 70).

A current limiting circuit 74 is provided between each charge/discharge changeover switch 72 and an electronic component W. The current limiting circuit 74 limits the current (in particular, the maximum current) flowing through the circuit, and allows the current to increase in accordance with an increase in applied voltage up to a certain applied voltage (hereinafter also referred to as a "limit voltage"), but allows only a basically constant current (a predetermined maximum current) for an applied voltage equal to or higher than the limit voltage. By providing the current limiting circuit 74, it is possible to prevent a current exceeding a specified maximum current value (for example, a maximum current value defined by standards such as JIS (Japanese Industrial Standards)) from flowing in the circuit.

The charge/discharge changeover switches 72 and the polarity changeover switches 73 are switched by the control unit 55 (see FIG. 3). Specifically, by switching the connection target of the charge/discharge changeover switches 72 between the resistor 71 and the polarity changeover switches 73 (and hence the power supply 70) under the control of the control unit 55, processing can be switched between charging processing and discharging processing of an electronic component W. In addition, by switching the connection target of the polarity changeover switches 73 between one of the charge/discharge changeover switches 72 and the other charge/discharge changeover switch 72 under the control of the control unit 55, the polarity of the applied voltage to be applied to an electronic component (capacitor) W is switched.

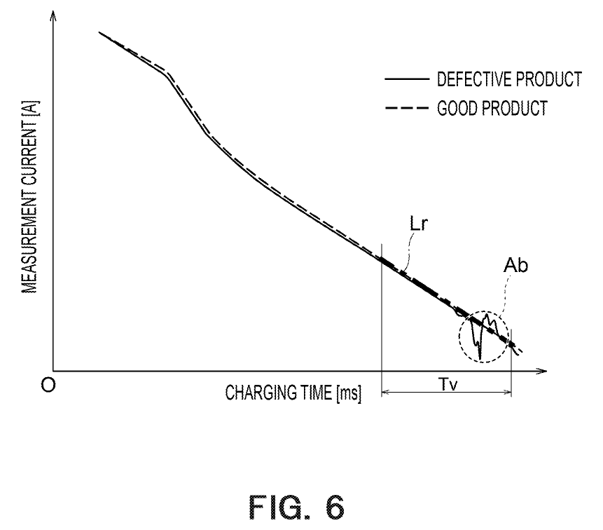

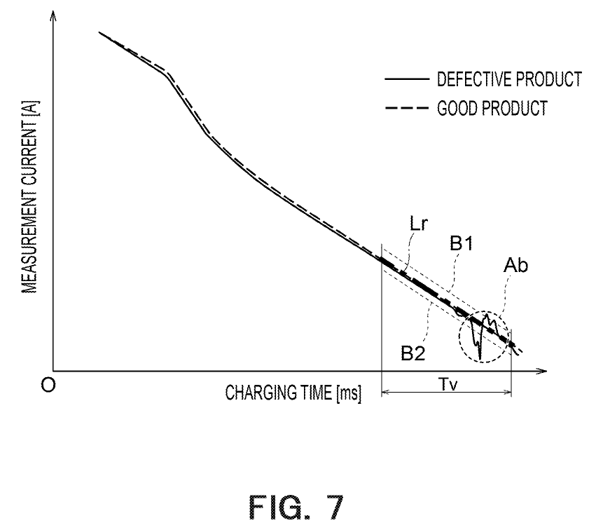

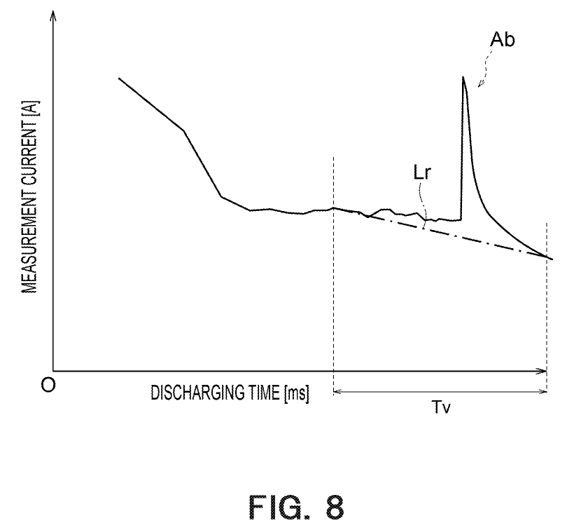

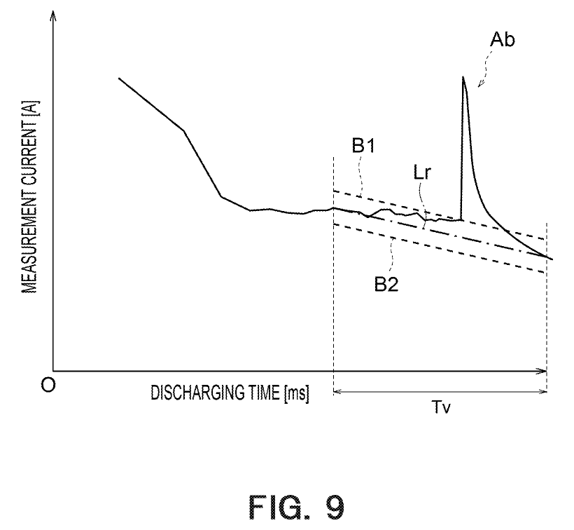

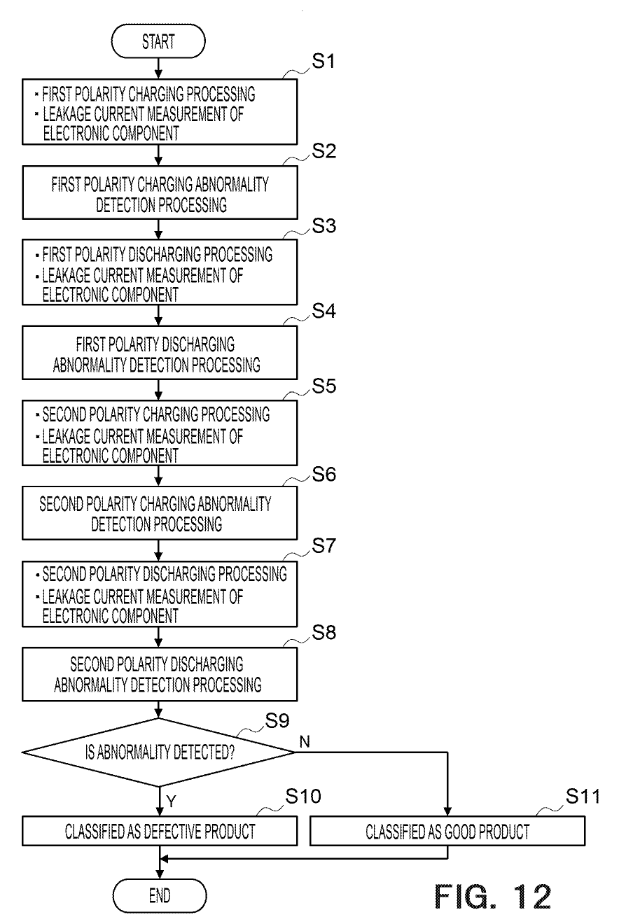

In this manner, by appropriately switching the charge/discharge changeover switches 72 and the polarity changeover switches 73 by the control unit 55, it is possible to switch between charging abnormality detection processing (see FIGS. 6 and 7 described later) and discharging abnormality detection processing (see FIGS. 8 and 9), or to switch between first polarity charging processing and second polarity charging processing (see FIG. 12 described later).

### Inspection Method

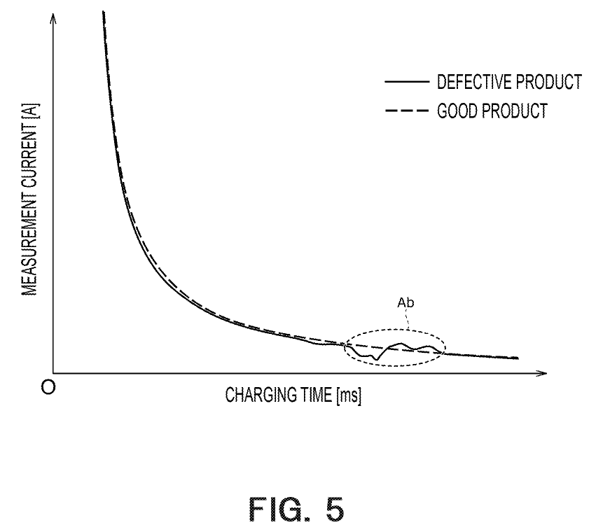

FIG. 5 is a graph (linear-scale graph) illustrating an example of a measurement result of leakage current of an electronic component W (capacitor) during charging. The X-axis in FIG. 5 indicates charging time (milliseconds (ms)), which is the elapsed time from the start of measurement (origin (O)), and the Y-axis indicates the measured value of the leakage current (amperes (A)) of an electronic component W.

FIG. 5 shows a measurement result of the leakage current of a normal electronic component (i.e., a "good product") that includes no abnormality and a measurement result of the leakage current of an electronic component having an abnormality (i.e., a "defective product"), obtained when a constant DC (direct current) voltage is applied to the electronic components W (capacitor) for charging.

As a result of repeated studies on the behavior of electrical characteristics (in particular, leakage current characteristics) of a capacitor (for example, an MLCC) during charging and discharging, the present inventors have newly discovered the fact that capacitors sometimes exhibit a temporary abnormal behavior during charging and/or discharging (see reference symbol "Ab" in FIG. 5).

Such abnormal behavior can be grasped from changes in a measured value of the leakage current of a capacitor; however, the measured value is not necessarily constant, and the amount of change of the measured value may be small. Further, the present inventors have newly discovered that there exist capacitors which exhibit abnormal behavior for a certain period of time (for example, several tens of milliseconds to several seconds), then return to normal behavior, and thereafter behave like good products.

In a conventional inspection device that detects an abnormality of a capacitor based on the peak value of the measured leakage current, it might be suitable for detecting an abnormality in which the leakage current suddenly increases, but it is not necessarily suitable for detecting an abnormality in which the leakage current decreases. In addition, with respect to a capacitor whose insulation property is not deteriorated but which has an abnormality in which the leakage current is unstable for some reason, the conventional inspection device cannot always sufficiently cope with such a capacitor.

Further, in recent years, MLCCs have been increasing in capacity; however, as the capacity increases, there is a tendency for a ceramic layer of an MLCC to become thinner, and it has become difficult to apply a high voltage to an MLCC for screening inspection. Therefore, there is a demand for a technique that realizes highly reliable screening inspection while keeping the applied voltage to an MLCC (capacitor) low.

For example, the apparatus of Japanese patent application publication No. 09-152455 detects a steep pulse-like abnormal current (leakage current) generated in a capacitor during charging. Such an apparatus of Japanese patent application publication No. 09-152455 is effective when the leakage current during charging exhibits stable behavior, but when the change in leakage current per unit time is relatively large, it is difficult to reliably detect abnormal current. Moreover, the apparatus of Japanese patent application publication No. 09-152455 cannot detect an abnormality in which the leakage current of a capacitor decreases.

Further, the apparatus of Japanese patent application publication No. 2000-228337 determines the acceptability of a capacitor based on whether an evaluation function that is defined from the actual measured current value of a capacitor and a standard selection current value, draws a convex curve with respect to either the upper side or the lower side. However, as also described in Japanese patent application publication No. 2000-228337 (see paragraph 0012), the apparatus of Japanese patent application publication No. 2000-228337 treats temporary changes in the actual measured current value of a capacitor as noise and does not detect them as abnormalities. Moreover, the apparatus of Japanese patent application publication No. 2000-228337 cannot detect an abnormality in which the leakage current of a capacitor decreases.

As a result of extensive studies based on the above findings, the present inventors have found a new technique capable of effectively and accurately detecting a capacitor abnormality that cannot be detected by conventional devices. Specifically, a new method has been found in which an abnormality of a capacitor is accurately detected based on a regression line derived from the logarithm of the measured values of the current (leakage current) of an electronic component W (capacitor) in a determination time range during charging and/or discharging, and the logarithm of the measurement timings of the current. According to this method, it is possible to accurately detect abnormal behavior temporarily exhibited by a capacitor having an abnormality during charging and/or discharging. In particular, even if the amount of change in the abnormal behavior is small, or even if the abnormal behavior continues only for a limited period of time (for example, several tens of milliseconds to several seconds), such abnormal behavior can be accurately detected.

Various variations of such abnormality detection methods can be considered, but any of the abnormality detection methods can detect abnormal behavior of a capacitor based on a regression line. Typical examples of such abnormality detection methods are shown below; however, abnormality detection methods that utilize a regression line in forms different from the following typical examples are also included in the present disclosure.

First, a method for detecting an abnormality of an electronic component W (capacitor) during charging will be described (see FIGS. 6 and 7), and thereafter, a method for detecting an abnormality of an electronic component W (capacitor) during discharging will be described (see FIGS. 8 and 9).

### First Charging Abnormality Detection Method

FIG. 6 is a graph (log-log graph) illustrating an example of a measurement result of leakage current of an electronic component W during charging, which is a graph for explaining the first charging abnormality detection method. The X-axis and Y-axis of FIG. 6 are based on logarithmic scales, the X-axis of FIG. 6 indicating in logarithm the charging time (milliseconds), which is the elapsed time from the start of measurement (origin (O)), and the Y-axis indicating in logarithm the measured value (amperes) of the leakage current of an electronic component W.

FIG. 6 shows a measurement result of the leakage current of a normal electronic component (i.e., a "good product") including no abnormality, and a measurement result of the leakage current of an electronic component having an abnormality (i.e., a "defective product") when a constant DC voltage is applied to the electronic components W (capacitors) for charging. FIG. 6 also shows a "regression line Lr" obtained based on the least squares method from the measurement results of the good product and the defective product.

According to the inspection method based on the first charging abnormality detection method, a charging step, a current measuring step, and an abnormality detecting step are performed under the control of the control unit 55.

In the charging step, an electronic component W (capacitor) is charged by applying a voltage by the electrical circuit 50 (charging unit 51A) in a state of being clamped by the probe 31 and the electrode 36 shown in FIG. 3. In the current measuring step, the current (leakage current of the capacitor) of the electronic component W during charging is continuously measured by the electrical circuit 50 (current measurement unit 52). In this manner, the current measuring step and the charging step are performed in parallel.

Then, in the abnormality detecting step, an abnormality of the electronic component W (capacitor) is detected by the control unit 55 (abnormality detecting unit) based on the regression line Lr derived from the logarithm of the measured values of the leakage current in the determination time range Tv during charging and the logarithm of the measurement timings of the leakage current. More specifically, the control unit 55 detects an abnormality of the electronic component W based on the degree of coincidence between the logarithm of the measured values of the leakage current and the logarithm of the measurement timings with respect to the regression line Lr.

The "determination time range Tv" here refers to a time range suitable for determining the presence or absence of an abnormality of the electronic component W, and is specifically set to a time range in which the degree of coincidence of the measurement results of the good product with respect to the regression line Lr is high. The optimal determination time range Tv is determined under the influence of the leakage current characteristics of the electronic component W and the applied voltage to the electronic component W, and may be set, for example, to a time range of 200 ms to 1500 ms after the start of charging (see the origin "O" in FIG. 6).

The "degree of coincidence between the logarithm of the measured values of the leakage current and the logarithm of the measurement timings with respect to the regression line Lr" is typically calculated as a coefficient of determination based on the least squares method. The specific method of calculating the coefficient of determination is not limited, and the coefficient of determination can be calculated using a known calculation formula.

For example, when the electronic component W is a good product, the "degree of coincidence between the logarithm of the measured values of the leakage current and the logarithm of the measurement timings with respect to the regression line Lr" becomes relatively high, and the value of the coefficient of determination (contribution ratio) based on the least squares method also becomes relatively large. When the coefficient of determination in a case where the logarithm of the measured values of the leakage current and the logarithm of the measurement timings completely coincide with the regression line Lr is expressed as "100%," the coefficient of determination of the electronic component W as a good product may be, for example, 95.0% or more. For example, the coefficient of determination of an electronic component W is 99.0% or more, the electronic component W may be classified as a good product.

On the other hand, when the electronic component W is a defective product, the "degree of coincidence between the logarithm of the measured values of the leakage current and the logarithm of the measurement timings with respect to the regression line Lr" becomes relatively low, and the value of the coefficient of determination also becomes relatively small, and may indicate a value smaller than 99.0% (for example, a value smaller than 95.0%). For example, the coefficient of determination of an electronic component W is less than 99.0%, the electronic component W may be classified as a defective product.

As described above, the inspection target electronic component W can be classified as a good product or a defective product based on the coefficient of determination, but the threshold value of the coefficient of determination serving as a classification criterion for good products and defective products is appropriately set according to the allowable degree of an actual abnormality. Specifically, the closer the threshold value is to "100%," the stricter the determination of the presence or absence of an abnormality becomes, and even a slight abnormality is not allowed, and as a result, the proportion of electronic components W determined to be defective tends to increase.

Therefore, the higher the requirement for reliability of the normality of the electrical characteristics (leakage current characteristics) of the electronic component W, the closer the threshold value of the coefficient of determination serving as a classification criterion for good products and defective products is set to "100%." In order to satisfy the high reliability required in recent advanced technologies, the threshold value of the coefficient of determination may be required to be set, for example, to "99.0%" or a value higher than "99.0%".

As described above, the "degree of coincidence between the logarithm of the measured values of the leakage current and the logarithm of the measurement timings with respect to the regression line Lr" represents the linearity of the logarithm of the measured values of the leakage current and the logarithm of the measurement timings, and can be expressed as a coefficient of determination based on the least squares method. However, the "degree of coincidence between the logarithm of the measured values of the leakage current and the logarithm of the measurement timings with respect to the regression line Lr" may be obtained based on any other method capable of directly or indirectly evaluating linearity on the log-log graph of "charging time versus measured current."

For example, the control unit 55 (abnormality detecting unit) may obtain a "degree of disagreement" between the logarithm of the measured values of the leakage current and the logarithm of the measurement timings with respect to the regression line Lr by any method, and may detect an abnormality of the electronic component W based on the degree of disagreement. The control unit 55 (abnormality detecting unit) may also extract only the data of the measured values of the leakage current of the inspection target electronic component W for a part of the time range (determination time range Tv) during the charging time. In this case, the control unit 55 may detect an abnormality of the electronic component W based on the regression line Lr derived from the logarithm of the extracted measured values of the leakage current and the logarithm of the measurement timings of the leakage current.

The control unit 55 controls the electronic component discharging unit 14 based on the result of the inspection including the above-described series of steps, and discharges electronic components W determined to be abnormal and electronic components W determined not to be abnormal into separate collection boxes of the collection device 16 via the discharge paths 15.

### Second Charging Abnormality Detection Method

In the following description regarding the second charging abnormality detection method, detailed descriptions of processes similar to those of the above-described first charging abnormality detection method (see FIG. 6) are omitted.

FIG. 7 is a graph (log-log graph) illustrating an example of a measurement result of leakage current of an electronic component W during charging, which is a graph for explaining the second charging abnormality detection method. The X-axis and Y-axis of FIG. 7 are expressed on logarithmic scales, the X-axis of FIG. 7 indicating in logarithm the charging time (milliseconds), which is the elapsed time from the start of measurement (origin (O)), and the Y-axis indicating in logarithm the measured value (amperes) of the leakage current of an electronic component W.

FIG. 7 shows the measurement result of an electronic component that is a good product, and the measurement result of an electronic component that is a defective product, and also shows a regression line Lr obtained based on the measurement results of the good product and the defective product. FIG. 7 also shows an upper limit B1 and a lower limit B2 of a current allowable range.

Also in the inspection method based on the second charging abnormality detection method, a charging step, a current measuring step, and an abnormality detecting step are performed, and in particular, the charging step and the current measuring step are performed in the same manner as in the inspection method based on the above-described first charging abnormality detection method.

However, in the abnormality detecting step based on the second charging abnormality detection method, the control unit 55 (abnormality detecting unit) determines whether or not the logarithm of the measured values of the leakage current of an electronic component W in the determination time range Tv is included in the current allowable range defined based on the regression line Lr. Specifically, an abnormality of an electronic component W (capacitor) is detected based on the relationship of the logarithm of the measured values of the leakage current with respect to at least one of the upper limit B1 and the lower limit B2 of the current allowable range defined based on the regression line Lr over the determination time range Tv.

In the log-log graph of FIG. 7, the region between the line indicated by reference sign "B1" (upper limit) and the line indicated by reference sign "B2" (lower limit) corresponds to the current allowable range, and the regression line Lr is present within the region (current allowable range) in the determination time range Tv.

As described above, an electronic component W to be inspected can be classified as a good product or a defective product based on the current allowable range (upper limit B1 and lower limit B2), and the upper limit B1 and lower limit B2 defining the current allowable range correspond to threshold values serving as classification criteria between good products and defective products, and are appropriately set according to the permissible degree of actual abnormality. Specifically, the closer the upper limit B1 and the lower limit B2 of the current allowable range are to the regression line Lr, the stricter the determination of the presence or absence of abnormality becomes, and even slight abnormalities are no longer tolerated, resulting in an increased tendency for electronic components W to be determined as defective. Therefore, the higher the requirement for reliability regarding the normality of the electrical characteristics (leakage current characteristics) of an electronic component W, the closer the upper limit B1 and the lower limit B2 of the current allowable range, which serve as classification criteria between good products and defective products, are set to the regression line Lr.

The specific method for determining the upper limit B1 and the lower limit B2 of the current allowable range is not limited. For example, the difference from the regression line Lr with respect to the measured current (see the Y-axis of FIG. 7) may be the same value between the upper limit B1 and the lower limit B2 of the current allowable range, or may be different values. Further, the difference in the measured current between the regression line Lr and the upper limit B1 or the lower limit B2 of the current allowable range may be the same throughout the entire determination time range Tv, or may not be the same. Accordingly, in the log-log graph of "charging time versus measured current" (see FIG. 7), the line indicating the upper limit B1 of the current allowable range and the line indicating the lower limit B2 thereof may be parallel or may be non-parallel to the regression line Lr.

The upper limit B1 and the lower limit B2 of the current allowable range may also be determined from the values of the regression line Lr (Y-axis values relating to the measured current) at a plurality of discrete time timings selected from the determination time range Tv. For example, with respect to two points, namely a "start time timing (start point)" and an "end time timing (end point)" of the determination time range Tv, the upper limit B1 and the lower limit B2 of the current allowable range may be determined based on the regression line Lr. In this case, in the log-log graph of "charging time versus measured current" (see FIG. 7), the upper limit B1 of the current allowable range over the entire determination time range Tv may be determined by a straight line passing through these two points (start point and end point) relating to the upper limit B1 of the current allowable range. Similarly, in the log-log graph of "charging time versus measured current," the lower limit B2 of the current allowable range over the entire determination time range Tv may be determined by a straight line passing through these two points (start point and end point) relating to the lower limit B2 of the current allowable range.

Further, the control unit 55 (abnormality detection unit) may set only one of the upper limit B1 and the lower limit B2 of the current allowable range to a value different from the regression line Lr. In this case, the other one of the upper limit B1 and the lower limit B2 of the current allowable range may be set to the same value as the regression line Lr.

In the above abnormality detection step, when the entirety of the measured current of an electronic component W in the determination time range Tv is within the current allowable range (including, for example, the boundaries (upper limit B1 and lower limit B2)), the control unit 55 can determine that the electronic component W has no abnormality. On the other hand, when at least a part of the measured current of an electronic component W in the determination time range Tv is outside the current allowable range (not including, for example, the boundaries (upper limit B1 and lower limit B2)), the control unit 55 can determine that the electronic component W has an abnormality.

Then, the control unit 55 controls the electronic component discharging unit 14 based on the results of the inspection including the above-described series of steps to discharge electronic components W determined to have an abnormality and electronic components W determined not to have an abnormality into separate collection boxes of the collection device 16 via the discharge paths 15.

Next, a method for detecting an abnormality of an electronic component W (capacitor) during discharge will be described (FIGS. 8 and 9).

### First discharge abnormality detection method

In the following description regarding the first discharge abnormality detection method, detailed descriptions of processes similar to those of the first charging abnormality detection method (see FIG. 6) and the second charging abnormality detection method (see FIG. 7) described above are omitted.

FIG. 8 is a graph (log-log graph) illustrating an example of a measurement result of leakage current of an electronic component W during discharge, which is a graph for explaining the first discharge abnormality detection method. The X-axis and Y-axis of FIG. 8 are represented on a logarithmic scale, the X-axis of FIG. 8 indicating in logarithm the discharge time (milliseconds), which is the elapsed time from the start of measurement (origin (O)), and the Y-axis indicating in logarithm the measured value (amperes) of the leakage current of an electronic component W.

FIG. 8 shows a measurement result of the leakage current of an electronic component W (i.e., a "defective product") having an abnormality when a resistor is connected to the electronic component W (capacitor) and discharge is performed. FIG. 8 also shows a "regression line Lr" obtained from measurement results based on the least squares method.

In the first discharge abnormality detection method, the current measurement and abnormality detection performed in the first charging abnormality detection method described above are performed for discharge of an electronic component W, instead of charging of an electronic component W. Specifically, according to the inspection method based on the first discharge abnormality detection method, a discharge step, a current measurement step, and an abnormality detection step are performed under the control of the control unit 55.

In the discharge step, an electronic component W (capacitor) is discharged while being connected to the resistor 71 (see FIG. 4) by the electrical circuit 50 (discharging unit 51B) in a state of being sandwiched between the probe 31 and the electrode 36 as shown in FIG. 3. In the current measurement step, the current (leakage current of the capacitor) of the electronic component W during discharge is continuously measured by the electrical circuit 50 (current measurement unit 52). Thus, the current measurement step and the discharge step are performed in parallel.

Then, in the abnormality detection step, an abnormality of the electronic component W (capacitor) is detected by the control unit 55 (abnormality detection unit) based on a regression line Lr derived from the logarithm of the measured values of the leakage current and the logarithm of the measurement timings of the leakage current in the determination time range Tv during discharge. More specifically, the control unit 55 detects an abnormality of the electronic component W based on the degree of coincidence between the logarithm of the measured values of the leakage current and the logarithm of the measurement timings of the leakage current with respect to the regression line Lr.

It is preferable that the "determination time range Tv" be set to a time range in which the degree of coincidence of the measurement results of good products (non-defective products) with respect to the regression line Lr is high. For example, the "determination time range Tv" may be set to a time range of 20 ms to 100 ms after the start of discharge (see the origin "O" in FIG. 8) at an early stage of discharge. Alternatively, the "determination time range Tv" may be set to a time range of 200 ms to 1500 ms after the start of discharge when the discharge current has decreased to some extent. However, these time ranges are merely examples of the "determination time range Tv," and the "determination time range Tv" may be set to any other arbitrary time range; for example, the "determination time range Tv" may be set to a range of 10 ms to 20 ms after the start of discharge.

The control unit 55 controls the electronic component discharging unit 14 based on the results of the inspection including the above-described series of steps to discharge electronic components W determined to have an abnormality and electronic components W determined not to have an abnormality into separate collection boxes of the collection device 16 via the discharge paths 15.

### Second Discharge Abnormality Detection Method

In the following description regarding the second discharge abnormality detection method, detailed descriptions of processes similar to those of the first charging abnormality detection method (see FIG. 6), the second charging abnormality detection method (see FIG. 7), and the first discharge abnormality detection method (see FIG. 8) described above are omitted.

FIG. 9 is a graph (log-log graph) illustrating an example of a measurement result of leakage current of an electronic component W during discharge, which is a graph for explaining the second discharge abnormality detection method. The X-axis and Y-axis of FIG. 9 are represented on logarithmic scale, the X-axis of FIG. 9 indicating in logarithm the discharge time (milliseconds), which is the elapsed time from the start of measurement (origin O), and the Y-axis indicating in logarithm the measured value (amperes) of the leakage current of an electronic component W.

In FIG. 9, a measurement result of a defective electronic component is shown, and a regression line Lr obtained based on the measurement results of both good and defective products is also shown. Furthermore, FIG. 9 shows the upper limit B1 and the lower limit B2 of the allowable current range.

The second discharge abnormality detection method performs the current measurement and abnormality detection that are performed in the second charging abnormality detection method described above, not during charging of an electronic component W but during discharge of an electronic component W. Specifically, also in the inspection method based on the second discharge abnormality detection method, a discharge step, a current measurement step, and an abnormality detection step are performed, and in particular, the discharge step and the current measurement step are performed in the same manner as in the inspection method based on the first discharge abnormality detection method described above.

However, in the abnormality detection step based on the second discharge abnormality detection method, the control unit 55 (abnormality detection unit) determines whether or not the logarithm of the measured values of the leakage current of an electronic component W in the determination time range Tv falls within the allowable current range defined based on the regression line Lr. Specifically, an abnormality of an electronic component W (capacitor) is detected based on the relationship of the logarithm of the measured values of the leakage current with respect to at least one of the upper limit B1 and the lower limit B2 of the allowable current range defined based on the regression line Lr over the determination time range Tv.

In the log-log graph of FIG. 9, the region between the line indicated by reference sign "B1" (upper limit) and the line indicated by reference sign "B2" (lower limit) corresponds to the allowable current range, and the regression line Lr lies within this region (allowable current range) in the determination time range Tv.

The specific manner of determining the upper limit B1 and the lower limit B2 of the allowable current range used in the present discharge abnormality detection method is not limited, and the upper limit B1 and the lower limit B2 of the allowable current range may be determined in the same manner as the upper limit B1 and the lower limit B2 of the allowable current range used in the second charging abnormality detection method (see FIG. 7) described above.

Accordingly, the upper limit B1 and the lower limit B2 of the allowable current range may be determined based on the values of the regression line Lr (Y-axis values corresponding to the measured current) at a plurality of discrete time timings selected from the determination time range Tv. Further, the control unit 55 (abnormality detection unit) may set only one of the upper limit B1 and the lower limit B2 of the allowable current range to a value different from the regression line Lr. In this case, the other one of the upper limit B1 and the lower limit B2 of the allowable current range may be set to the same value as the regression line Lr.

In the abnormality detection step described above, when the entire measured current of an electronic component W in the determination time range Tv lies within the allowable current range (including, for example, the boundaries: upper limit B1 and lower limit B2), the control unit 55 can determine that the electronic component W has no abnormality. On the other hand, when at least a part of the measured current of an electronic component W in the determination time range Tv lies outside the allowable current range (excluding, for example, the boundaries: upper limit B1 and lower limit B2), the control unit 55 can determine that the electronic component W has an abnormality.

Then, the control unit 55 controls the electronic component discharging unit 14 based on the results of the inspection including the above-described series of steps to discharge electronic components W determined to have an abnormality and electronic components W determined not to have an abnormality into separate collection boxes of the collection device 16 via the discharge paths 15.

### Application Examples of Abnormality Detection Methods

The first and second charging abnormality detection methods (see FIGS. 6 and 7), the first and second discharging abnormality detection methods (see FIGS. 8 and 9), or other charging abnormality detection methods or discharging abnormality detection methods based on the regression line Lr can be applied to the inspection method of an electronic component W as described below, whereby it becomes possible to accurately detect an abnormality of the electronic component W.

### Application Example 1

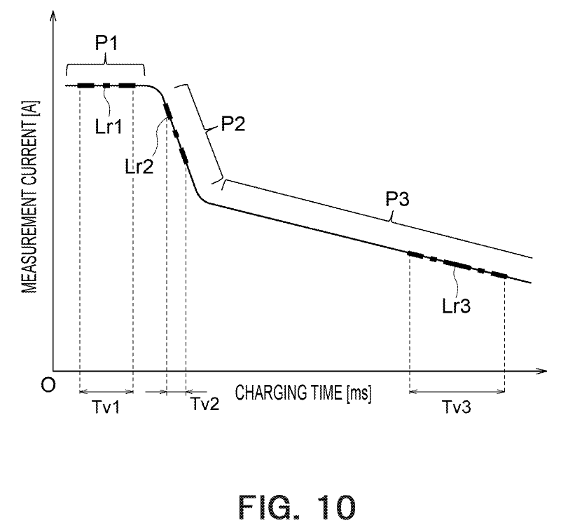

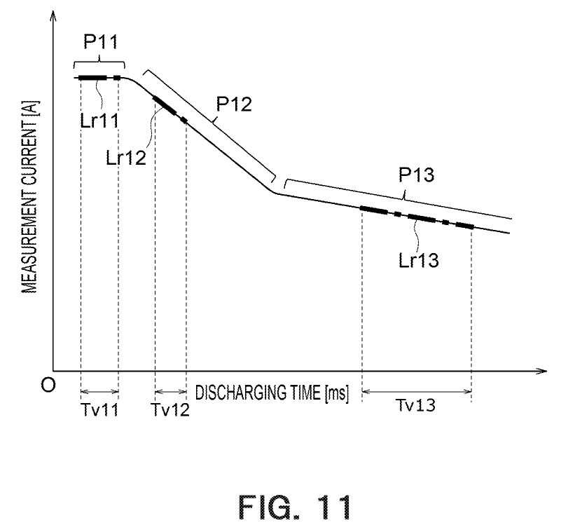

FIG. 10 is a log-log graph of "charging time versus measured current" showing an example of a general electrical characteristic of a capacitor. FIG. 11 is a log-log graph of "discharging time versus measured current" showing an example of a general electrical characteristic of a capacitor.

In a case where a constant DC voltage is applied to a capacitor to perform charging, the correlation between the logarithm of the charging time of the capacitor and the logarithm of the leakage current is not necessarily constant over the entire charging time, and there exist a plurality of phases that exhibit inherent linearity (proportional relationship) (see "P1" to "P3" in FIG. 10). In the example shown in FIG. 10, there exist a first phase P1 in which the leakage current of a capacitor is almost constant, a second phase P2 in which the leakage current rapidly decreases, and a third phase P3 in which the leakage current decreases more rapidly than that in the first phase P1 and more gradually than that in the second phase P2. In the log-log graph shown in FIG. 10, "charging time versus measured current" shows a proportional correlation in each of the first to third phases P1 to P3, but the proportion of the proportional correlation of "charging time versus measured current" (that is, the slope of the linearity) differs among the first to third phases P1 to P3.

Similarly, the correlation between the logarithm of the discharge time of a capacitor and the logarithm of the leakage current when a resistor is connected to the capacitor to perform discharge is not necessarily constant over the entire discharge time, and there exist a plurality of phases (see "P11" to "P13" in FIG. 11) that exhibit inherent linearity (proportional relationship). In the example shown in FIG. 11, there exist a first phase P11 in which the leakage current of a capacitor is almost constant, a second phase P12 in which the leakage current rapidly decreases, and a third phase P13 in which the leakage current decreases more rapidly than that in the first phase P11 and more gradually than that in the second phase P12. In the log-log graph shown in FIG. 11, "discharge time versus measured current" shows a proportional correlation in each of the first to third phases P11 to P13, but the proportion of the proportional correlation of "discharge time versus measured current" (that is, the slope of the linearity) differs among the first to third phases P11 to P13.

The control unit 55 (abnormality detection unit) can detect an abnormality of an electronic component W (capacitor) for each phase by setting the determination time range Tv and the regression line Lr for each phase.

For example, the control unit 55 can detect an abnormality of an electronic component W in a first determination time range based on a first regression line derived from the logarithm of the measured values of the leakage current of the electronic component W in the first determination time range during charging and the logarithm of the measurement timings of this leakage current. On the other hand, the control unit 55 can detect an abnormality of an electronic component W in a second determination time range based on a second regression line derived from the logarithm of the measured values of the leakage current of the electronic component W in the second determination time range during charging and the logarithm of the measurement timings of this leakage current.

By setting the "first determination time range" and the "second determination time range" to different phases (see the first phase P1, the second phase P2, and the third phase P3 in FIG. 10), it is possible to detect an abnormality of an electronic component W in each of the plurality of phases. If there exist three or more phases in the correlation between the charging time of a capacitor and the leakage current, three or more determination time ranges may be set so as to be assigned to the respective phases.

For example, in the example shown in FIG. 10, the "first determination time range Tv1" may be set for the first phase P1, the "second determination time range Tv2" may be set for the second phase P2, and the "third determination time range Tv3" may be set for the third phase P3. In this case, a first regression line Lr1 is determined based on the measurement result of the leakage current in the first determination time range Tv1, a second regression line Lr2 is determined based on the measurement result of the leakage current in the second determination time range Tv2, and a third regression line Lr3 is determined based on the measurement result of the leakage current in the third determination time range Tv3. Then, using the above-described abnormality detection methods (see FIGS. 6 and 7), an abnormality of an electronic component W in the first determination time range Tv1 can be detected based on the first regression line Lr1, an abnormality of an electronic component W in the second determination time range Tv2 can be detected based on the second regression line Lr2, and an abnormality of an electronic component W in the third determination time range Tv3 can be detected based on the third regression line Lr3.

The "first determination time range" and the "second determination time range" may be set in the same phase. For example, in one phase occupying a relatively long time range (see the third phase P3 in FIG. 10), the "first determination time range" and the "second determination time range" (and the third and subsequent determination time ranges) may be set.

Similarly, the control unit 55 can detect an abnormality of an electronic component W in a first determination time range during discharge based on a first regression line derived from the logarithm of the measured values of the leakage current of the electronic component W in the first determination time range and the logarithm of the measurement timings of this leakage current. On the other hand, the control unit 55 can detect an abnormality of an electronic component W in a second determination time range during discharge based on a second regression line derived from the logarithm of the measured values of the leakage current of the electronic component W in the second determination time range and the logarithm of the measurement timings of this leakage current.

By setting the "first determination time range" and the "second determination time range" to different phases (see the first phase P11, the second phase P12, and the third phase P13 in FIG. 11), it is possible to detect an abnormality of an electronic component W in each of the plurality of phases. If three or more phases exist in the correlation between the discharge time of a capacitor and the leakage current, three or more determination time ranges may be set so as to be assigned to the respective phases.

For example, in the example shown in FIG. 11, a "first determination time range Tv11" may be set for the first phase P11, a "second determination time range Tv12" may be set for the second phase P12, and a "third determination time range Tv13" may be set for the third phase P13. In this case, a first regression line Lr11 is determined based on the measurement result of the leakage current in the first determination time range Tv11, a second regression line Lr12 is determined based on the measurement result of the leakage current in the second determination time range Tv12, and a third regression line Lr13 is determined based on the measurement result of the leakage current in the third determination time range Tv13. Then, using the above-described abnormality detection methods (see FIGS. 8 and 9), an abnormality of an electronic component W in the first determination time range Tv11 can be detected based on the first regression line Lr11, an abnormality of an electronic component W in the second determination time range Tv12 can be detected based on the second regression line Lr12, and an abnormality of an electronic component W in the third determination time range Tv13 can be detected based on the third regression line Lr13.

The "first determination time range" and the "second determination time range" may be set in the same phase. For example, in one phase occupying a relatively long time range (see the third phase P13 in FIG. 11), the "first determination time range" and the "second determination time range" (and the third and subsequent determination time ranges) may be set.

### Application Example 2

The inspection device 13 may perform a plurality of electrical inspections on each electronic component W. Such a plurality of electrical inspections may include two electrical inspections in which the polarity (direction of the positive and negative electrodes) of the current (direct current) when applying an inspection voltage to each electronic component W is different from each other.

Specifically, in the electrical circuit 50 (see FIG. 3), after the charging unit 51A applies a voltage to an electronic component W (capacitor) with a first polarity to perform first polarity charging, the discharging unit 51B may connect the electronic component W to the resistor 71 (see FIG. 4) to perform first polarity discharging. Further, after the first polarity charging and the first polarity discharging, the charging unit 51A may apply a voltage to an electronic component W with a second polarity that is opposite to the first polarity to perform second polarity charging, and thereafter, the discharging unit 51B may connect the electronic component W to the resistor 71 (see FIG. 4) to perform second polarity discharging.

In this case, the electrical circuit 50 (current measurement unit 52) measures a first polarity charging current, which is the leakage current of an electronic component W during first polarity charging, measures a first polarity discharging current, which is the leakage current of an electronic component W during first polarity discharging, measures a second polarity charging current, which is the leakage current of an electronic component W during second polarity charging, and measures a second polarity discharging current, which is the leakage current of an electronic component W during second polarity discharging.

Then, the control unit 55 (abnormality detection unit) can detect an abnormality of an electronic component W (capacitor) based on a first polarity regression line derived from the logarithm of the measured values of the first polarity charging current in the first determination time range during first polarity charging and the logarithm of the measurement timings of the first polarity charging current. Further, the control unit 55 can detect an abnormality of an electronic component W (capacitor) based on a second polarity regression line derived from the logarithm of the measured values of the second polarity charging current in a second determination time range during second polarity charging and the logarithm of the measurement timings of the second polarity charging current. When a negative voltage is applied to an electronic component W (for example, in a case of second polarity charging), the measured value of the leakage current of the electronic component W (for example, the second polarity charging current) also becomes a negative value, and therefore, the regression line may be derived from the logarithm of the absolute value of the measured value of the leakage current.

Similarly, the control unit 55 (abnormality detection unit) can detect an abnormality of an electronic component W (capacitor) based on a first polarity regression line derived from the logarithm of the measured values of the first polarity discharging current in a first determination time range during first polarity discharging and the logarithm of the measurement timings of the first polarity discharging current. Further, the control unit 55 can detect an abnormality of an electronic component W (capacitor) based on a second polarity regression line derived from the logarithm of the measured values of the second polarity discharging current in a second determination time range during second polarity discharging and the logarithm of the measurement timings of the second polarity discharging current. When discharging is performed immediately after a negative voltage is applied to an electronic component W (for example, in a case of second polarity discharging), the measured value of the leakage current of the electronic component W (for example, the second polarity discharging current) also becomes a negative value, and therefore, the regression line may be derived from the logarithm of the absolute value of the measured value of the leakage current.

A capacitor of an electronic component W may exhibit unique electrical characteristics depending on the polarity of the applied current, and may exhibit an abnormal behavior in leakage current only in one of the cases where a voltage of a first polarity is applied or a voltage of a second polarity is applied. Even if an electronic component W to be inspected has such polarity dependency, abnormalities of the electronic component W can be reliably detected by performing electrical inspections with respect to each of the first polarity and the second polarity as in the present application example.

The phenomenon that "a capacitor of an electronic component W may exhibit unique electrical characteristics depending on the polarity" can appear not only as an electrical characteristic during charging but also as an electrical characteristic during discharging. Accordingly, it is preferable that, after the above-described detection of a charging abnormality during first polarity charging (first polarity charging abnormality detection; see FIGS. 6 and 7), the discharging abnormality detection (first polarity discharging abnormality detection; see FIGS. 8 and 9) is performed. Specifically, it is preferable that the current measurement unit 52 measure the first polarity charging current, which is the current of an electronic component W during first polarity charging, and thereafter measure the first polarity discharging current, which is the current of the electronic component W during first polarity discharging.

Furthermore, thereafter, it is preferable that, after the above-described detection of a charging abnormality during second polarity charging (second polarity charging abnormality detection; see FIGS. 6 and 7), the discharging abnormality detection (second polarity discharging abnormality detection; see FIGS. 8 and 9) is performed. Specifically, it is preferable that the current measurement unit 52 measure the second polarity charging current, which is the current of an electronic component W during second polarity charging, and thereafter measure the second polarity discharging current, which is the current of the electronic component W during second polarity discharging.

FIG. 12 is a flowchart illustrating an example of an inspection method for detecting an abnormality of an electronic component W (capacitor). The flowchart of FIG. 12 illustrates an example of an inspection flow performed by one inspection process by the inspection device 13, and when the inspection process by the inspection device 13 is repeatedly performed, the inspection flow shown in FIG. 12 is repeatedly performed.

In the inspection system 10 of the example shown in FIGS. 1 and 2, intermittent rotation and intermittent stopping of the index table 11 are performed in such a manner that a plurality of electronic components W to be inspected are placed at an inspection position where inspection by the inspection device 13 is performed (in particular, a region covered by the second front cover 62 (see the probe units 30 shown in FIG. 3)). Then, while the index table 11 is intermittently stopped, the inspection flow shown in FIG. 12 is performed, and accordingly it is determined whether each of the plurality of electronic components W to be inspected is classified as a good product or a defective product.

Specifically, first, while the first polarity charging processing of the plurality of electronic components W to be inspected is simultaneously performed, leakage currents of the respective electronic components W are measured (S1 in FIG. 12), and based on the results of the measurement, the presence or absence of an abnormality during charging of each electronic component W is determined (first polarity charging abnormality detection processing; S2).

Thereafter, while the discharging processing (first polarity discharging processing) of the plurality of electronic components W to be inspected that have undergone first polarity charging is simultaneously performed, leakage currents of the respective electronic components W are measured (S3), and based on the results of the measurement, the presence or absence of an abnormality during discharging of each electronic component W is determined (first polarity discharging abnormality detection processing; S4).

Thereafter, while the second polarity charging processing of the plurality of electronic components W to be inspected after the first polarity discharging processing is simultaneously performed, leakage currents of the respective electronic components W are measured (S5), and based on the results of the measurement, the presence or absence of an abnormality during charging of each electronic component W is determined (second polarity charging abnormality detection processing; S6).

Thereafter, while the discharging processing (second polarity discharging processing) of the plurality of electronic components W to be inspected that have undergone second polarity charging is simultaneously performed, leakage currents of the respective electronic components W are measured (S7), and based on the results of the measurement, the presence or absence of an abnormality during discharging of each electronic component W is determined (second polarity discharging abnormality detection processing; S8).

Then, any electronic component W in which an abnormality is detected in at least one or more of the above-described series of abnormality detection processes (S2, S4, S6, S8) is classified as a defective product (Y in S9, S10). On the other hand, any electronic component W in which no abnormality is detected in any of the above-described series of abnormality detection processes (S2, S4, S6, S8) is classified as a good product (N in S9, S11).

In the example shown in FIG. 12, the above various abnormality detection processes (S2, S4, S6, S8) are performed as separate steps immediately after the corresponding leakage current measurements of a plurality of electronic components W to be inspected are performed, but they may alternatively be performed collectively in a single step (for example, in step S9 shown in FIG. 12). In this case, "the first polarity charging processing and the leakage current measurement (S1)", " the first polarity discharging processing and the leakage current measurement (S3)", " the second polarity charging processing and the leakage current measurement (S5)", and " the second polarity discharging processing and the leakage current measurement (S7)" can be continuously performed.

Further, the above-described various abnormality detection processes (S2, S4, S6, S8) and the quality classification processes (S9, S10, S11) are not necessarily required to be performed in a state where a plurality of electronic components W to be inspected are located at the inspection position (at a region covered by the second front cover 62 (see FIGS. 1 and 2)). Specifically, the various abnormality detection processes (S2, S4, S6, S8) and the quality classification processes (S9, S10, S11) only need to be performed before a discharge process in which a plurality of electronic components W to be inspected are discharged to the corresponding collection device 16 through the discharge paths 15 at the discharge position (in particular, a region covered by the third front cover 63 (see FIGS. 1 and 2)). Therefore, the various abnormality detection processes (S2, S4, S6, S8) and the quality classification processes (S9, S10, S11) may be performed while a plurality of electronic components W to be inspected are being moved from the inspection position to the discharge position.

As described above, according to the inspection device 13 and the inspection method described above, it is possible to detect an abnormality of an electronic component W (capacitor) based on a regression line Lr derived from a logarithm of a measured value of leakage current of the electronic component W and a logarithm of a measurement timing of the leakage current in determination time range Tv during each of charging and discharging.

In particular, even when an electronic component W having an abnormality exhibits abnormal behavior only temporarily during charging or discharging, the above inspection device 13 and inspection method can appropriately detect such an abnormality of an electronic component W. Furthermore, even when the behavior of leakage current of an electronic component W is unstable and the amount of change in the leakage current is small, the above inspection device 13 and inspection method can appropriately detect such an abnormality of an electronic component W.

Further, according to the above inspection device 13 and inspection method, not only an abnormality in which the leakage current of an electronic component W increases but also an abnormality in which the leakage current decreases can be detected. Further, even when the inspection voltage applied to an electronic component W to be inspected is low, an abnormality of the electronic component W can be reliably detected.

There are cases where an electronic component W whose leakage current fluctuates relatively greatly per unit time even in a normal state is to be inspected, but according to the above second charging abnormality detection method (see FIG. 7) and/or the second discharging abnormality detection method (see FIG. 9), it is also possible to accurately detect an abnormality of such an electronic component W. Specifically, by determining the upper limit B1 and/or lower limit B2 of the allowable current range in consideration of the magnitude of fluctuation of the leakage current in the normal state of an electronic component W, it is possible to prevent fluctuations of the leakage current in the normal state from being detected as "abnormal," while detecting the true "abnormality" of the electronic component W. Furthermore, according to the above second charging abnormality detection method and/or the second discharging abnormality detection method, it is also possible to detect an "abnormality in which the insulation of an electronic component W (capacitor) is not deteriorated, but the leakage current is unstable for some reason."

Further, according to the above inspection system 10 and inspection method, not only an abnormality of an electronic component W during charging but also an abnormality of an electronic component W during discharging can be appropriately detected. In particular, during charging, the capability (influence) of the charging power supply is inevitably reflected in the abnormality detection result, whereas during discharging, the influence (noise) of the charging power supply is essentially absent, so that the individual characteristics of an electronic component (capacitor) W tend to be more strongly reflected in the abnormality detection result. Therefore, according to inspection based on the discharging abnormality detection result, even a slight abnormality or a transient abnormality of an electronic component W that is difficult to detect in a normal inspection, can be appropriately detected.

In particular, since the discharging abnormality detection process is performed after the corresponding charging abnormality detection process, it is also possible to detect an abnormality of an electronic component W that has occurred due to the corresponding charging abnormality detection process.

Further, when an electronic component W is charged for inspection, the electronic component W is normally discharged after charging from the viewpoint of safety and the like. Specifically, regardless of whether the discharging abnormality detection is to be performed, the charging process and the discharging process of an electronic component W are usually performed continuously. Accordingly, even when the discharging abnormality detection process is performed in addition to the charging abnormality detection process, it is possible that the total time required for the detection process does not substantially increase or increases only slightly compared to the case where only the charging abnormality detection process is performed.

In the example shown in FIG. 12, the charging abnormality detection process and the discharging abnormality detection process corresponding to each other are performed as a set; however, the charging abnormality detection process may be performed without performing the discharging abnormality detection process, or the discharging abnormality detection process may be performed without performing the charging abnormality detection process.

As described above, the inspection device 13 of the present embodiment includes: the charging unit 51A that charges an electronic component (capacitor) W; the discharging unit 51B that discharges an electronic component W; the current measurement unit 52 that continuously measures the current of an electronic component W during discharging; and the control unit (abnormality detection unit) 55 that detects an abnormality of an electronic component W based on a regression line Lr relating to a discharging characteristic, the regression line being derived from the logarithm of the measured current values in a determination time range Tv during discharging and the logarithm of the current measurement timings.

Further, the current measurement unit 52 continuously measures the current of an electronic component W during charging, and the control unit 55 is capable of detecting an abnormality of an electronic component W based on a regression line Lr relating to a charging characteristic, the regression line being derived from the logarithm of the measured current values in a determination time range Tv during charging and the logarithm of the current measurement timings.

Further, the control unit 55 is capable of detecting an abnormality of an electronic component W based on the degree of coincidence between the logarithm of the measured current values and the logarithm of the measurement timings with respect to the regression line Lr.

Further, the control unit 55 is capable of detecting an abnormality of an electronic component W based on a relationship of the logarithm of the measured current values with respect to at least one of an upper limit B1 and a lower limit B2 of an allowable current range, the allowable current range being defined with reference to the regression line Lr over the determination time range Tv.

Further, the control unit 55 is capable of detecting an abnormality of an electronic component W based on a first regression line Lr11 that is derived from the logarithm of the measured current values in a first determination time range Tv11 during discharging and the logarithm of the measurement timings of the current, and is capable of detecting an abnormality of an electronic component W based on a second regression line Lr12 that is derived from the logarithm of the measured current values in a second determination time range Tv12 during discharging and the logarithm of the measurement timings of the current.

After the charging unit 51A applies a voltage to an electronic component W with a first polarity to perform first polarity charging, the discharging unit 51B performs first polarity discharging of the electronic component W; after the charging unit 51A applies a voltage to an electronic component W with a second polarity to perform second polarity charging, the discharging unit 51B performs second polarity discharging of the electronic component W; the current measurement unit 52 measures a first polarity discharging current, which is a current of the electronic component W during the first polarity discharging, and measures a second polarity discharging current, which is a current of the electronic component W during the second polarity discharging; the control unit 55 detects an abnormality of an electronic component W based on the first polarity regression line Lr, which is derived from the logarithm of the measured values of the first polarity discharging current in the first determination time range Tv11 during the first polarity discharging and the logarithm of the measurement timings of the first polarity discharging current, and is capable of detecting an abnormality of an electronic component W based on the second polarity regression line Lr, which is derived from the logarithm of the measured values of the second polarity discharging current in the second determination time range Tv12 during the second polarity discharging and the logarithm of the measurement timings of the second polarity discharging current.

The inspection method of the present embodiment includes a step of charging an electronic component W, a step of discharging the electronic component W, a step of continuously measuring the current of the electronic component W during discharging, and a step of detecting an abnormality of the electronic component W based on a regression line Lr, which is derived from the logarithm of the measured current values in a determination time range Tv during discharging and the logarithm of the measurement timings of the current.

It should be noted that the embodiments and modifications disclosed in this specification are merely illustrative in all respects and should not be construed as limiting. The above embodiments and modifications may be omitted, substituted, or altered in various forms without departing from the scope and spirit of the appended claims. For example, the above embodiments and modifications may be combined in whole or in part, and embodiments other than those described above may be combined with the above embodiments or modifications. Further, the effects of the present disclosure described in this specification are merely illustrative, and other effects may also be obtained.

The technical category for embodying the above-described technical idea is not limited. For example, the above-described technical idea may be embodied by a computer program for causing a computer to execute one or more procedures (steps) included in a method for manufacturing or using the above-described device. Further, the above-described technical idea may be embodied by a non-transitory recording medium readable by a computer on which such a computer program is recorded.

1. An inspection device comprising:
a charging unit that performs charging of a capacitor;
a discharging unit that performs discharging the capacitor;
a current measurement unit that continuously measures current of the capacitor during the discharging; and
an abnormality detection unit that detects an abnormality of the capacitor based on a regression line relating to a discharge characteristic, the regression line being derived from a logarithm of measured values of the current in a determination time range during the discharging and a logarithm of measurement timings of the current.

2. The inspection device as defined in claim 1, wherein:
the current measurement unit continuously measures the current of the capacitor during the charging, and
the abnormality detection unit detects an abnormality of the capacitor based on a regression line relating to a charging characteristic, the regression line being derived from a logarithm of measured values of the current in a determination time range during the charging and a logarithm of measurement timings of the current.

3. The inspection device as defined in claim 1, wherein the abnormality detection unit detects an abnormality of the capacitor based on a degree of coincidence between the logarithm of the measured values of the current and the logarithm of the measurement timings of the current with respect to the regression line.

4. The inspection device as defined in claim 1, wherein the abnormality detection unit detects an abnormality of the capacitor based on a relationship of the logarithm of the measured values of the current with respect to at least one of an upper limit and a lower limit of a current allowable range determined with reference to the regression line over the determination time range.

5. The inspection device as defined in claim 1,
wherein the abnormality detection unit detects an abnormality of the capacitor based on a first regression line derived from a logarithm of measured values of the current in a first determination time range during the discharging and a logarithm of measurement timings of the current, and
wherein the abnormality detection unit detects an abnormality of the capacitor based on a second regression line derived from a logarithm of measured values of the current in a second determination time range during the discharging and a logarithm of measurement timings of the current.

6. The inspection device as defined in claim 1, wherein:
after the charging unit applies a voltage to the capacitor with a first polarity to perform first polarity charging, the discharging unit performs first polarity discharging of the capacitor;
after the charging unit applies a voltage to the capacitor with a second polarity to perform second polarity charging, the discharging unit performs second polarity discharging of the capacitor;
the current measurement unit measures a first polarity discharging current which is a current of the capacitor during the first polarity discharging;
the current measurement unit measures a second polarity discharging current which is a current of the capacitor during the second polarity discharging;
the abnormality detection unit detects an abnormality of the capacitor based on a first polarity regression line derived from a logarithm of measured values of the first polarity discharging current in a first determination time range during the first polarity discharging and a logarithm of measurement timings of the first polarity discharging current; and
the abnormality detection unit detects an abnormality of the capacitor based on a second polarity regression line derived from a logarithm of measured values of the second polarity discharging current in a second determination time range during the second polarity discharging and a logarithm of measurement timings of the second polarity discharging current.

7. An inspection method comprising the steps of:
performing charging of a capacitor;
performing discharging the capacitor;
measuring current of the capacitor during the discharging in a continuous manner; and
detecting an abnormality of the capacitor based on a regression line relating to a discharge characteristic, the regression line being derived from a logarithm of measured values of the current in a determination time range during the discharging and a logarithm of measurement timings of the current.
